(19) United States
(12) Patent Application Publication
(10) Pub. No.: US 2012/0301979 A1
(43) Pub. Date: Nov. 29, 2012

(54) System and Method for Preconditioning Photovoltaic Modules for Performance Testing

(75) Inventors: Michelle Propst, Fort Collins, CO (US); Lawrence J. Knipp, Fort Collins, CO (US)

(73) Assignee: ABOUND SOLAR, INC., Loveland, CO (US)

(21) Appl. No.: 13/116,966

(22) Filed: May 26, 2011

(51) Int. Cl. H01L 31/18; H01L 21/66

(52) U.S. Cl. 438/17; 257/E31.001; 257/E21.531

(57) ABSTRACT

A system and method for preconditioning a photovoltaic device is described. One embodiment includes a method for preconditioning a photovoltaic device, the method comprising applying a forward-bias to the photovoltaic device, wherein a forward-bias current is equal to or greater than I_{MP(FB)} for the photovoltaic device.

### FIELD OF THE INVENTION

The present invention relates to preconditioning photovoltaic modules (or photovoltaic panel) for performance testing.

### BACKGROUND OF THE INVENTION

Photovoltaic (PV) module (or panel) manufacturers, distributors, and end-users all have an interest in being able to determine the performance of their PV modules. Unfortunately, transient or metastable current-voltage (I-V) characteristics inhibit the accurate determination of PV module performance and reliability. The transient characteristics of polycrystalline PV modules, such as cadmium telluride (CdTe) or copper indium gallium diselenide (CIGS) photovoltaics, can cause errors in energy ratings and service-lifetime predictions. While there is disagreement about what causes the metastable behavior of CdTe and CIGS devices, the fact that transient I-V phenomena inhibit the accurate determination of PV module performance is well-known.

In order to minimize or eliminate the errors caused with these transient characteristics, it is recommended that a PV module be preconditioned for 8 hours under natural sunlight. Given the impracticality of such lengthy preconditioning in an industry setting, however, some have proposed reducing the preconditioning time to around two hours under natural sunlight or using an artificial light-soak. While the second option offers a significant improvement in preconditioning time, two hours is still a significant time period for manufacturers, distributors, or consumers to wait before being able to determine PV module performance.

In order to help improve the effectiveness of preconditioning (i.e., more closely approximate maximum PV module performance) and to reduce the time period required for preconditioning, methods such as baking (placing the PV module in an environment at elevated temperatures, such as a thermal anneal oven), artificial light-soak (exposing the PV module to lamps with bulbs designed to approximate real sunlight) and combinations thereof have been proposed. These methods, however, still suffer from significant preconditioning time and also create significant costs. Most distributors and consumers are unlikely to have the expensive equipment, such as thermal anneal ovens, necessary to use baking techniques, and are equally unlikely to own the often costly lamps that are used to simulate real sunlight.

In a recent conference paper, Cueto, et al. proposed another method of preconditioning using a “forward-biased dark exposure at elevated temperature.” (Cueto, et al., “Striving for a Standard Protocol for Preconditioning or Stabilization of Polycrystalline Thin Film Photovoltaic Modules,” Conference Paper, NREL/CP-520-44935, July 2009 (hereinafter “Cueto, et al.”).) In this paper, Cueto, et al. disclose preconditioning using “forward-bias (voltage controlled) exposure under dark conditions (dark-soak) at 60° C., with bias between V_{OC} and the optimum power point voltage (V_{MAX}).” (Cueto, et al. at 3-4.) Cueto, et al.'s disclosure is limited in that it relies on an elevated temperature environment and describes a limited voltage controlled forward-bias range. Once again, the equipment required for the preconditioning in Cueto, et al. is expensive and often beyond the access of many distributors and consumers. It is often not practical for a manufacturer to place panels in an elevated temperature environment in order to precondition before performance testing.

Although present methods and devices are functional, they are not sufficiently accurate or otherwise satisfactory. Accordingly, a system and method are needed to address the shortfalls of present technology and to provide other new and innovative features.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The present invention can provide a system and method for preconditioning a photovoltaic device. In one exemplary embodiment, the present invention can include a method for preconditioning a photovoltaic device, the method comprising applying a forward-bias to the photovoltaic device, wherein a forward-bias current is equal to or greater than I_{MP(FB)} for the photovoltaic device. Applying the forward-bias may comprise applying a current controlled forward-bias, applying a constant forward-bias current, applying a variable forward-bias current, applying a voltage controlled forward-bias, or applying a variable forward-bias voltage. The effective forward-bias current may be sustained at a value equal to or greater than I_{MP(FB)} for the photovoltaic device, or at a value greater than I_{SC(FB)}. The forward-bias may be applied for a conditioning time, wherein the conditioning time is based on a magnitude of the forward-bias current.

In another embodiment, the present invention may comprise a method for preconditioning a photovoltaic device, the method comprising applying a forward-bias current to the photovoltaic device, wherein a forward-bias current is substantially equal to or greater than I_{MP(FB)} for the photovoltaic device. In yet another embodiment, applying a forward-bias for preconditioning may comprise applying a first forward-bias for a first time period; and applying a second forward-bias for a second time period. The magnitude of the first forward-bias may be the same or different than the second forward-bias, and the length of the first time period and the second time period may be the same or different. In one embodiment, the magnitude of the first forward-bias is the same as the magnitude of the second forward-bias, and the length of the first time period and the second time period are different. In one embodiment, the magnitude of the first forward-bias is different than the magnitude of the second forward-bias, and the length of the first time period and the second time period are the same. In one embodiment, the magnitude of the first forward-bias is different than the magnitude of the second forward-bias, and the length of the first time period and the second time period are different.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 illustrates exemplary current-voltage (I-V) curves for a photovoltaic (PV) module;

FIG. 2 illustrates a flow chart for preconditioning a PV module consistent with the present invention;

FIG. 3 illustrates an exemplary block diagram for a system for preconditioning a PV panel consistent with the present invention;

FIG. 4 illustrates another flow chart for preconditioning a PV panel consistent with the present invention; and

FIG. 5 illustrates yet another flow chart for preconditioning a PV module consistent with the present invention.

### DETAILED DESCRIPTION

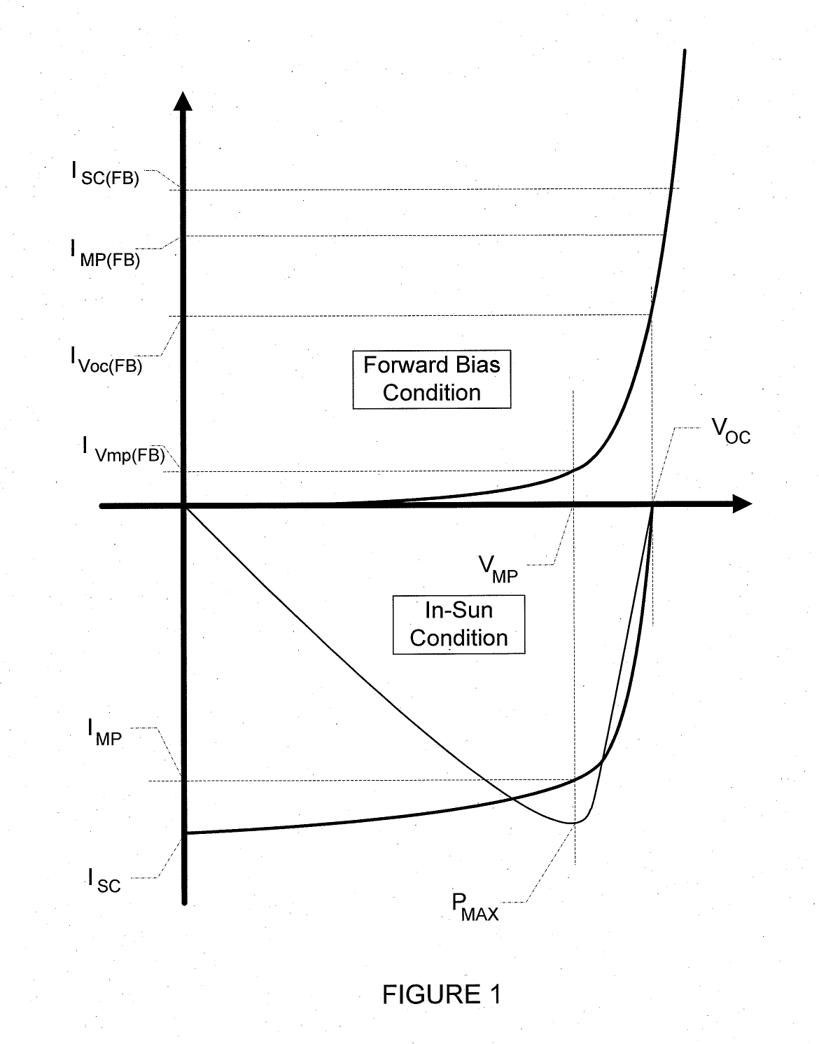

Referring now to the drawings, where like or similar elements are designated with identical reference numerals throughout the several views, and referring in particular to FIG. 1, it illustrates exemplary current-voltage (I-V) curves for a photovoltaic (PV) module. In particular, FIG. 1 shows an I-V curve for an in-sun condition and an I-V curve for a forward-bias condition. In addition, a power curve is also shown for the in-sun condition.

In general, an in-sun I-V curve shows the possible combinations of current and voltage output for a PV module at standard conditions. At one end of the in-sun I-V curve, the maximum current output of the module, the short circuit current (I_{SC}), occurs when the resistance drops to zero. At the other end, the maximum voltage of the device, the open circuit voltage (V_{OC}), occurs when the circuit is broken or when the resistance grows infinitely large. The maximum power point (P_{MAX}) occurs somewhere in-between these two points, on the knee of the I-V curve. The voltage and current at this maximum power point are labeled V_{MP} and I_{MP}, respectively.

As is understood by those of skill in the art, an in-sun I-V curve is determined using standard conditions of sunlight (i.e., one sun or 1000 W/m²) and standard device temperature. It is noted that when these conditions change, the in-sun I-V curve may also change.

For the forward-bias condition, the I-V curve is representative of the PV module acting as a power consumer, rather than a power producer. Although the shape of the forward-bias I-V curve is similar to the in-sun I-V curve, the shapes of the curves are not the same. This is due to multiple factors. For example, the resistance characteristics of the PV module can vary based on being in an illuminated state (e.g., an in-sun condition) or a dark state (e.g., a forward-bias condition). Moreover, for the forward-bias condition there is no current flow until the barrier potential of the forward diode is overcome. Just as the in-sun IV curve will vary for different PV modules, and different types of PV modules, the forward-bias I-V curve for different PV modules, and different types of PV modules, will also vary. It is further notable that the forward-bias I-V curve is not a fixed curve. Just as the in-sun I-V curve is affected by changes in sunlight and temperature, a forward-bias I-V curve can also fluctuate due to certain operational factors such as temperature and loading conditions. Accordingly, FIG. 1 is exemplary only and is not intended to be limited to any specific PV module.

The present invention provides a method for preconditioning PV modules using an applied forward-bias, wherein the forward-bias current is substantially equal to, or greater than, I_{MP(FB)}. By applying a forward-bias that is substantially equal to I_{MP(FB)} the preconditioning time can be reduced to less than ten (10) minutes without the need for light-soak or an elevated temperature environment. Moreover, as the forward-bias is increased, the preconditioning time can be further reduced. For example, in one embodiment, a forward-bias that is substantially equal to I_{SC(FB)} may be used in order to reduce the preconditioning time to less than one (1) minute. In yet another embodiment, the magnitude of the forward-bias current may be a multiple of the magnitude of I_{MP} for the PV module (e.g., a 1.5·I_{MP(FB)}, a 2·I_{MP(FB)}, 3·I_{MP(FB)}, 4·I_{MP(FB)}, etc.) in order to reduce preconditioning time to less than forty-five (45) seconds, or even less than thirty (30) seconds.

Referring again to FIG. 1, applying a forward-bias current of I_{MP(FB)} means applying either a voltage controlled forward-bias or a current controlled forward-bias such that the resulting forward-bias current in the PV module is I_{MP(FB)}. The variable I_{MP(FB)} represents a forward-bias current that is equal in magnitude to the I_{MP} of the PV module. Similarly, the variable I_{SC(FB)} represents a forward-bias current that is equal in magnitude to the I_{SC} of the PV module. The variable I_{Voc(FB)} represents the forward-bias current that results from applying a forward-bias voltage equal in magnitude to the V_{OC} of the device. Similarly, the variable I_{Vmp(FB)} represents the forward-bias current that results from applying a forward-bias voltage equal in magnitude to the V_{MP} of the device. As used herein, the I_{MP}, I_{SC}, V_{MP}, and V_{OC} are all based on standard conditions.

It should be understood that if a fixed forward-bias voltage is used, the effective forward-bias current of the PV module may vary over time. As discussed above, the forward-bias I-V curve for the device can fluctuate due to certain operational factors such as temperature, loading conditions, and the incoming state of the module (e.g, from dark storage versus a partially lighted environment). As the temperature of the PV module increases due to the applied forward-bias, the shape of the forward-bias I-V curve can change. Thus, for the same forward-bias voltage, the effective forward-bias current will increase over time as the forward-bias is sustained.

For purposes of the present invention, a voltage controlled forward-bias or a current controlled forward-bias method may be used. Here, the terms voltage controlled and current controlled reflect the fact that during forward-biasing, the forward-bias I-V curve may change. Thus, while the forward-bias voltage is controlled (this includes holding the voltage at a constant value or varying the voltage in a controlled manner) the effective forward-bias current is not.

Alternatively, the forward-bias current may be controlled while the effective applied voltage is not controlled. Once again, changes in operational characteristics of the PV module can affect the forward-bias I-V curve resulting in changes to the relationship between current and voltage.

In one embodiment, a current controlled forward-bias is used, wherein the forward-bias current is sustained at a value substantially equal to, or greater than, I_{MP(FB)}. In another embodiment, a current controlled forward-bias is used, wherein the forward-bias current is sustained at a value equal to, or greater than, I_{SC(FB)}. In yet another embodiment, a voltage controlled forward-bias is used, wherein the effective forward-bias current is sustained at a value substantially equal to, or greater than, I_{MP(FB)}. In accordance with these and other embodiments a forward-bias of sufficient magnitude can be used to significantly reduce preconditioning and eliminate the need for light-soak or an elevated temperature environment. Various embodiments will be readily apparent to those of skill in the art based on the present description.

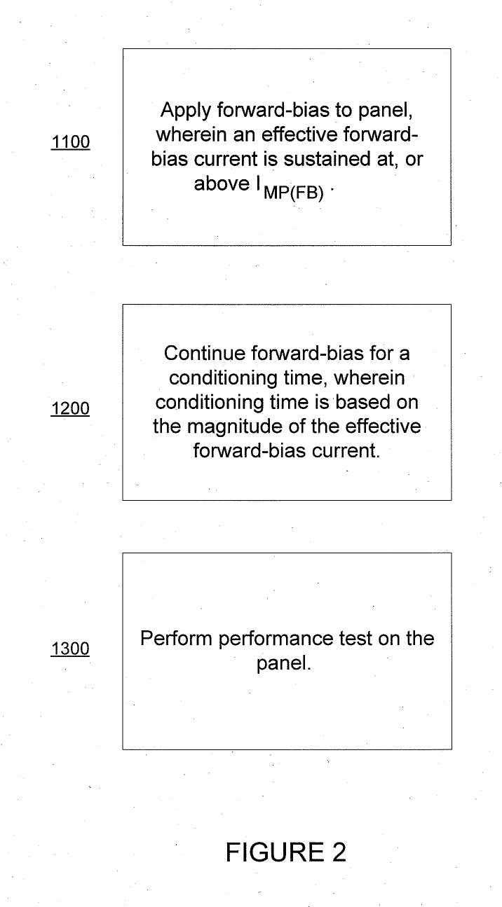

Referring now to FIG. 2, there is flow chart consistent with embodiments of the present invention. As shown in FIG. 2, the present invention simplifies the process for preconditioning (1100, 1200) and performance testing (1300) PV modules. In order to precondition the module, a forward-bias is applied to the panel wherein the effective forward-bias current is sustained at, or above I_{MP(FB)} (1100). In another embodiment, the effective forward-bias current may be below I_{MP(FB)} but still sufficiently high to reduce preconditioning time to one (1) minute or less. The forward-bias is continued for a conditioning time based on the magnitude of the effective forward-bias current (1200). The conditioning time is the amount of time the PV module needs to be conditioned in order to sufficiently approximate optimal use conditions. Generally, as the magnitude of the forward-bias current is increased, the length of time the forward-bias needs to be applied (the conditioning time) is reduced.

Due to variances between different types of PV modules (CdTe, CIGS, amorphous silicon (a-Si), etc.), between different PV module manufacturers and even between individual modules, a relationship between forward-bias current and conditioning time for all PV modules cannot be defined. However, a person of skill in the art can easily determine the conditioning time for a manufacturer's PV modules. This can be achieved by comparing (a) the optimal performance test results for a PV module using previously adopted preconditioning, with (b) the performance test results received using various conditioning times consistent with the present invention.

Although a precise relationship between forward-bias current and conditioning time cannot be established for all embodiments, initial testing provides the following guideposts for the conditioning time required based on the magnitude of the forward-bias current (measured as compared to a multiple of I_{MP(FB)}):

TABLE 1

| FORWARD-BIAS CURRENT | CONDITIONING TIME | |
|---|---|---|
| 1. I_{MP(FB)} | 4-6 | minutes |
| 2. I_{MP(FB)} | 1-3 | minutes |
| 3. I_{MP(FB)} | 40-120 | seconds |
| 4. I_{MP(FB)} | 20-60 | seconds |

Referring again to FIG. 2, once the preconditioning (1100, 1200) is complete a performance test can be performed on the panel (1300). It is preferred that the performance test be performed as soon as possible after the forward-bias is removed. For example, in preferred embodiments the performance test is performed within ten (10) seconds of applying the forward-bias (i.e., within ten (10) seconds after the forward-bias is complete the performance test is performed). In further embodiments, the performance test is performed within five (5) seconds, three (3) seconds, or one (1) second of applying the forward-bias.

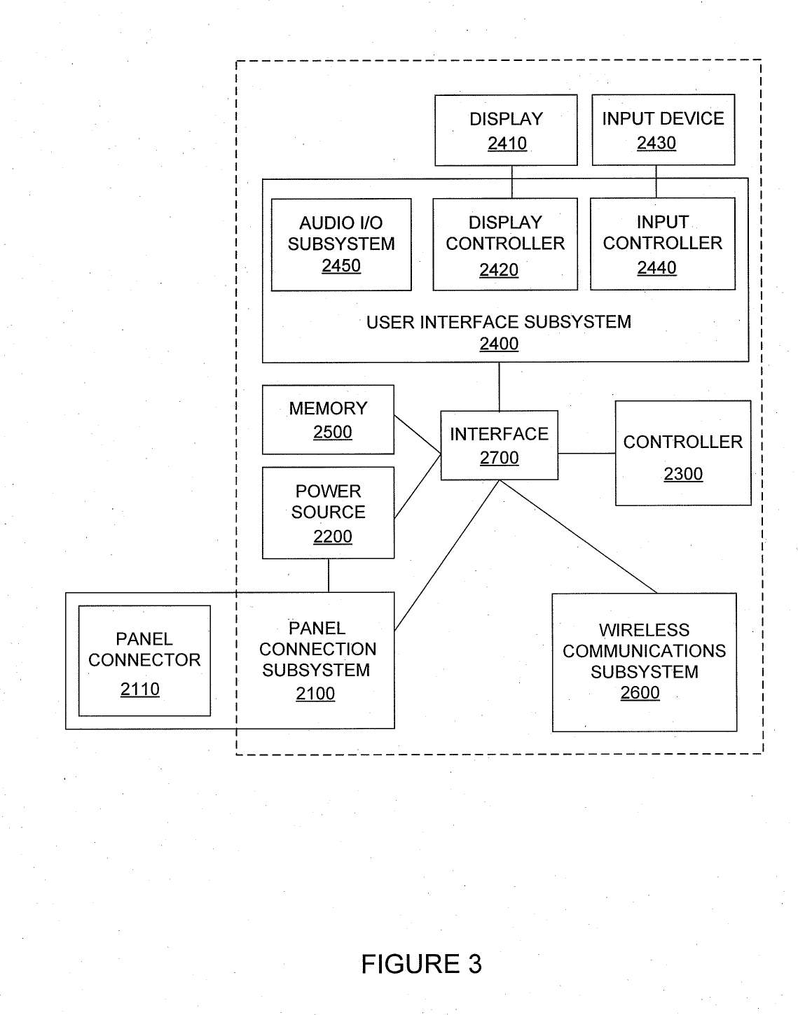

In FIG. 3 a block diagram for an exemplary system 2000 for preconditioning a PV panel is shown. The system in FIG. 3 includes a PV panel connector 2110 for connecting to the PV panel (not shown); a power source 2200, a controller 2300 and a user interface subsystem 2400. The PV panel connector 2110 allows the device 2000 to connect to the PV panel. The connector 2110 may comprise a standardized connector that is configured to be able to connect to different panels from different manufacturers. In another embodiment, the panel connector 2110 may comprise a universal adaptor which connects to specialized connectors designed specifically for panels from individual manufacturers. A power source 2200, such as a DC power source, is connected to the PV panel connector 2200, so that the device can be used to apply the forward-bias to the panel. The device controller 2300 controls the power source 2200 according to the use of the device 2000. The user interface subsystem 2400 allows for information to be provided to and/or received from a user. The user interface subsystem 2400 may comprise a display 2410 and display controller 2420 and an input device 2430 and an input controller 2440. In one embodiment, a touch screen display may be used for the display 2400 and input device 2430.

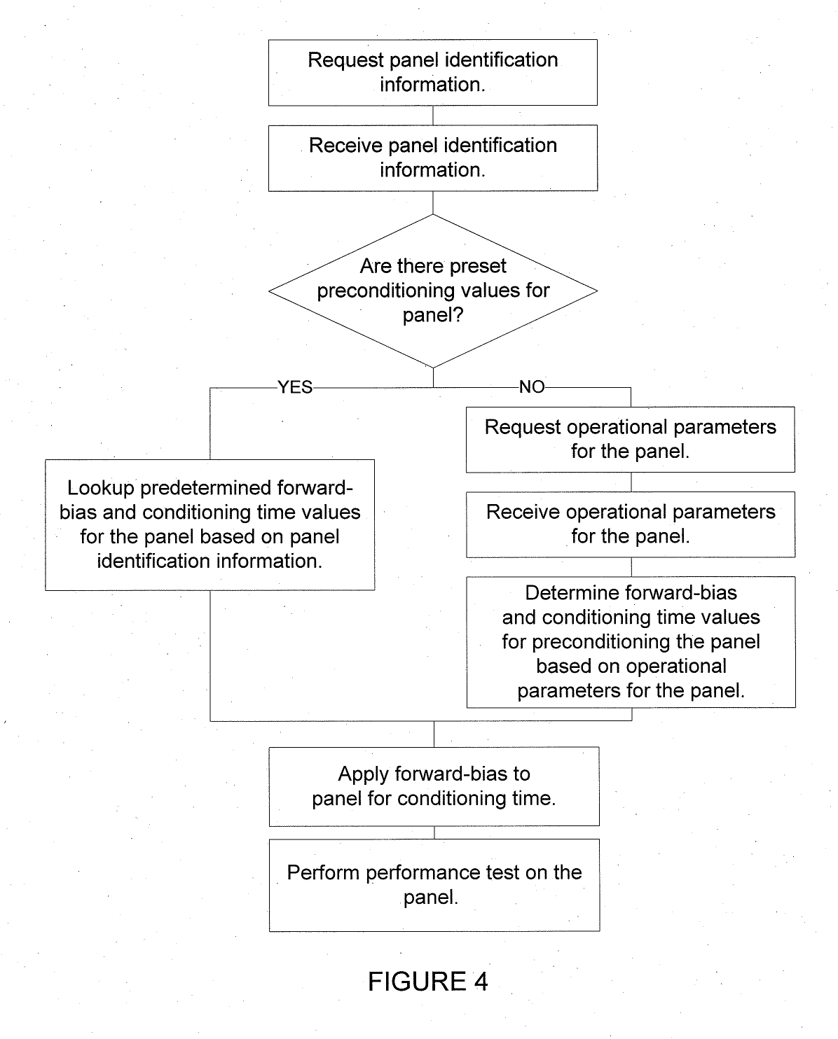

In one embodiment, the controller 2300 may contain computer-readable instructions for preconditioning PV panels using a forward-bias. For example, the flow-chart in FIG. 4 is consistent with an exemplary set of computer-readable instructions that could be used.

Referring now to FIG. 4, in this exemplary embodiment the controller 2300 may be configured to request panel identification information from a user. This panel identification information may be any type of information to identify the panel, such as serial number, manufacturer information, model number, etc. The request for panel identification information may be a visual and/or audible request through the user interface system 2400. The user interface 2400 may then allow a user to input a response that is provided to the controller 2300. The controller 2300 may then determine whether there are preset preconditioning values for the panel. For example, the controller 2300 may comprise, or be connected to, a memory 2500 that contains preset preconditioning values for various PV modules. In yet another embodiment, the controller 2300 may be configured to acquire preconditioning information for the panel based on the panel identification information (e.g., using the wireless communications subsystem 2600). If the controller 2300 is able to determine that there are preset preconditioning values for the panel, or otherwise acquire preconditioning values, the controller 2300 will then look up the predetermined forward-bias and conditioning time values for the panel.

If, however, the controller 2300 is unable to acquire preset precondition values the controller 2300 may still determine precondition values using the operational parameters of the panel. For example, the controller 2300 may request and receive operational parameters for the panel (e.g., I_{MP}, V_{OC}, I_{SC}, maximum recommended voltage, maximum recommended current, etc.). These operational parameters may then be used to determine the proper forward-bias and conditioning time for the panel. For example, if a user enters an I_{MP} for the panel, the controller 2300 could select to apply a forward-bias of I_{MP(FB)} for a predetermined conditioning time of 4-6 minutes. In this way, the device 2300 can be programmed to operate within the operational parameters of the panel. The conditioning time may be set based on a length of time generally known to be sufficient for the selected forward-bias. Referring back, by way of example, to Table 1, a conditioning time of 150 seconds could be selected when the forward-bias is 3·I_{MP(FB)} (a value 25% greater than the high end of the conditioning time range for 3·I_{MP(FB)}).

In another embodiment, there may be an option for the user to input a forward-bias and conditioning time for the panel. This may be a separate option, or it may be incorporated with the flow chart in FIG. 4. Those of skill in the art will be aware of various combinations, additions, and modifications consistent with the present invention.

It is further notable that the device 2000 in FIG. 3 may be configured to ramp into the forward-bias. Even a short ramping period (less than a tenth ( 1/10) of a second) can help protect the power source 2200 and the PV module from potential overloading. In one example, the controller 2300 can control the power source 2200 so that the forward-bias current is increased gradually over a period of 1 second, ½ of a second, or 1/10 of a second. In another embodiment, a forward-bias voltage may be similarly controlled.

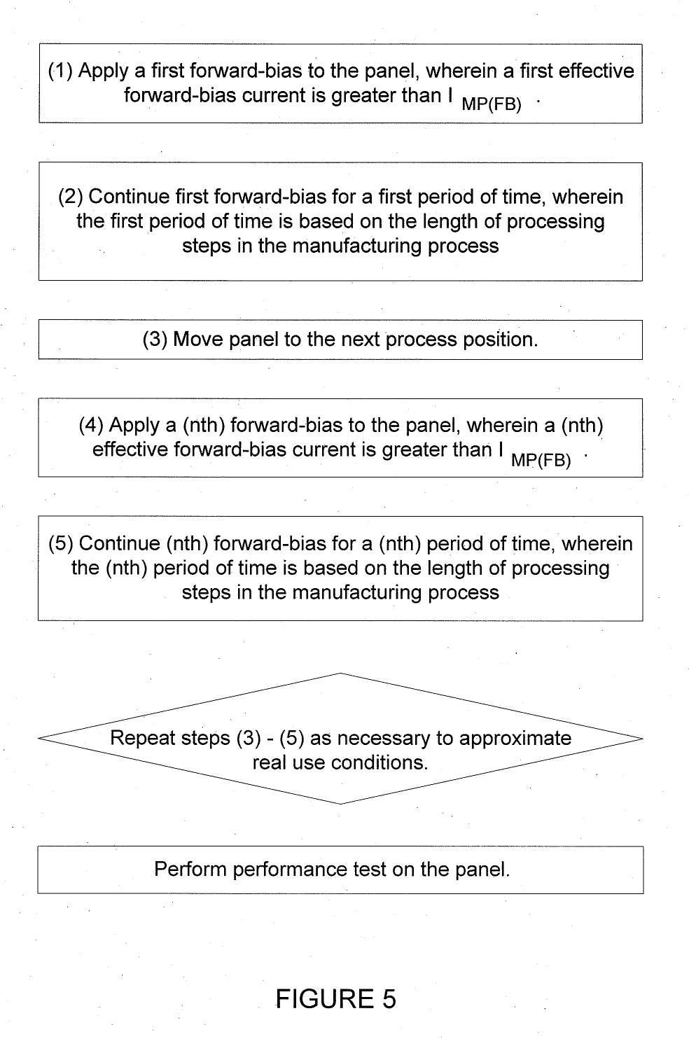

Referring now to FIG. 5 there is a further embodiment of the present invention for use in a manufacturing process. As shown in FIG. 5, the present invention is not limited to constant application of the same forward-bias. Instead, the forward-bias may be applied intermittently and/or the magnitude of the forward-bias may be varied. In FIG. 5, the intermittent nature of the forward-bias application is to reflect possible manufacturing conditions. In an assembly line manufacturing process, the forward-bias may need to be moved, or advanced, according to certain processing time periods. For example, if each processing step in a manufacturing process is allotted 30 seconds, it may be preferential to advance the PV module every 30 seconds. Rather than redesigning the actual manufacturing line equipment, it may be most efficient to apply the forward-bias within the length of each processing step. However, because the length of the processing steps may not provide a sufficient time period to precondition, it may be necessary to use multiple processing step time periods in order to ensure the device has been sufficiently preconditioned before performance testing.

Referring to FIG. 5, in steps (1) and (2) a forward-bias is applied to the panel for a period of time based on the length of the processing steps in the manufacturing process. In step (3) the PV panel is then moved to the next process position. In this embodiment, the forward-bias current is ramped to a value greater than I_{MP(FB)}. Because a forward-bias is not constantly applied, the magnitude of the forward-bias that is applied during each time period depends on, at least in part, the total amount of conditioning time (the sum of all the time periods during which a forward-bias is applied) and the amount of time between applications of a forward-bias. Likewise, determining the conditioning time (or the total number of time periods required) is based, at least in part, on the magnitude of each forward-bias that is applied during each time period and the amount of time between applications of a forward-bias. A forward-bias is once again applied in steps (4) and (5) in order to further precondition the PV panel. The forward-bias in steps (1) and (2) does not necessarily need to be the same as the forward-bias in steps (4) and (5). Moreover, even if steps (3)-(5) are repeated, the magnitude of the forward-bias in each repetition of steps (4) and (5) does not need to be the same. The magnitude of the forward-bias for each application may be easily determined by those of skill in the art based on the present disclosure. As described previously, experimental testing using a PV panel for which results are known can be used to determine whether preconditioning parameters are sufficient.

In conclusion, the present invention provides, among other things, a system and method for preconditioning photovoltaic devices. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A method for preconditioning a photovoltaic device, the method comprising:
applying a forward-bias to the photovoltaic device, wherein a forward-bias current is equal to or greater than I_{MP(FB)} for the photovoltaic device.

2. The method of claim 1, wherein applying the forward-bias comprises:
applying a current controlled forward-bias.

3. The method of claim 2, wherein applying the current controlled forward-bias comprises:
applying a constant forward-bias current.

4. The method of claim 2, wherein applying the current controlled forward-bias comprises:
applying a variable forward-bias current.

5. The method of claim 1, wherein applying the forward-bias comprises:
applying a voltage controlled forward-bias.

6. The method of claim 5, wherein applying the voltage controlled forward-bias comprises:
applying a variable forward-bias voltage, wherein the effective forward-bias current is sustained at a value equal to or greater than I_{MP(FB)} for the photovoltaic device.

7. The method of claim 1, wherein the effective forward-bias current is greater than I_{SC(FB)}.

8. The method of claim 1, wherein the effective forward-bias current is greater than 1.5·I_{MP(FB)}.

9. The method of claim 1, wherein the effective forward-bias current is greater than 2·I_{MP(FB)}.

10. The method of claim 1, further comprising:
applying the forward-bias for a conditioning time, wherein the conditioning time is based on a magnitude of the forward-bias current.

11. The method of claim 1, further comprising:
performing a performance test on the photovoltaic device.

12. The method of claim 11, wherein the performance test is performed within 5 seconds after applying the forward-bias to the photovoltaic device.

13. The method of claim 11, wherein a single device is used to apply the forward-bias and measure performance during the performance test.

14. The method of claim 1, wherein applying the forward-bias comprises:
ramping up to the forward-bias.

15. A method for preconditioning a photovoltaic device, the method comprising:
applying a forward-bias to the photovoltaic device, wherein a forward-bias current is substantially equal to or greater than I_{MP(FB)} for the photovoltaic device.

16. A method for preconditioning a photovoltaic device, the method comprising:
applying a first forward-bias for a first time period; and
applying a second forward-bias for a second time period.

17. The method of claim 16, wherein the first forward-bias is different than the second forward-bias.

18. The method of claim 16, wherein the first time period is and the second time period are the same length.

19. The method of claim 16, further comprising:
performing a performance test after the second time period.

20. The method of claim 16, further comprising:
applying a third forward-bias for a third time period.
